(19) United States
(12) Patent Application Publication
(10) Pub. No.: US 2008/0186045 A1
(43) Pub. Date: Aug. 7, 2008

(54) TEST MARK STRUCTURE, SUBSTRATE SHEET LAMINATE, MULTILAYERED CIRCUIT SUBSTRATE, METHOD FOR INSPECTING LAMINATION MATCHING PRECISION OF MULTILAYERED CIRCUIT SUBSTRATE, AND METHOD FOR DESIGNING SUBSTRATE SHEET LAMINATE

(75) Inventors: Yoji UEDA, Osaka (JP); Tsukasa SHIRAISHI, Osaka (JP); Yositake HAYASHI, Osaka (JP); Rikiya OKIMOTO, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 12/023,144

(22) Filed: Jan. 31, 2008

(30) Foreign Application Priority Data
Feb. 1, 2007 (JP) JP 2007-023557
Jan. 23, 2008 (JP) JP 2008-012988

(51) Int. Cl. G01R 31/02; H05K 1/00; H05K 3/36

(52) U.S. Cl. 324/763; 174/255; 29/830

(57) ABSTRACT

An inspection mark structure has an inspection via hole, which is provided in substrate sheets to be heat-pressed constituting at least two layers of laminates; a round pattern electrode, which is formed on one main face side of the substrate sheet provided with the inspection via hole, and provided around the end face of the inspection via hole at such a predetermined distance as not to come into contact with the end face; and a conduction electrode, which is formed on the other main face side of the substrate sheet provided with the inspection via hole, and provided so as to be electrically connected with the end face of the inspection via hole.

### BACKGROUND OF THE INVENTION

1. Field of the Invention

The present invention relates to an inspection mark structure, a substrate sheet laminate, a multilayered circuit substrate, a method for inspecting lamination matching precision of a multilayered circuit substrate, and a method for designing a substrate sheet laminate.

2. Related art of the Invention

With reduction in size and increase in density of electronic equipment, multilayered circuit substrates are in increasing demand not only in the field of industrial products but beyond, in the field of consumer products.

The multilayered circuit substrate is made up by laminating a plurality of substrates formed by providing a conductive via hole on the inside of a substrate material constituted of ceramic, prepreg or the like and an electrode pattern on the surface thereof. With this substrate applied, it is possible to reduce a size of a circuit as well as to increase its density.

Ensuring a high yield is an issue in such a multilayered circuit substrate. The multilayered circuit substrate is completed by laminating a plurality of substrates and performing heat-treating and compression-bonding (hereinafter referred to as heat-pressing), but when a laminated position of the substrate is displaced, connection failure, such as a short circuit, between a via hole and an electrode occurs inside the formed laminated circuit substrate, and the substrate becomes defective. Especially in such a case as ALIVH (registered trademark), a multilayered circuit having a structure where layers are connected using a conductive paste, each substrate is more apt to be displaced due to extension of a material during heat-pressing or the like.

Since correcting displacement of the laminated position is not possible in a completed multilayered circuit substrate, it is of importance in yield improvement of the multilayered circuit substrate to enhance lamination matching precision of each substrate. Further, with the demand for an increased density of the multilayered circuit substrate, the number of laminated substrates has been increased and a circuit pattern has been more miniaturized, and it has been demanded for enhancing the lamination matching precision of the multilayered circuit substrate from the viewpoint of not only ensuring a high yield, but also increasing performance.

Under the circumstances, a variety of pre-inspections have been performed in order to ensure the lamination matching precision of the multilayered circuit substrate. As an example thereof, in the lamination matching precision inspection, there has been performed an inspection using an X-ray transmission device by means of a mark structure for recognizing displacement of a via hole or a circuit pattern layer in each layer constituting a multilayered circuit substrate (e.g. Japanese Patent Laid-Open Application No. 2000-340950).

In the following, a conventional inspection mark structure of a multilayered circuit substrate and a conventional lamination matching precision inspection using the structure are described.

FIG. 18A is a view showing a multilayered circuit substrate formed by performing heat pressing on a substrate sheet laminate provided with the conventional inspection mark structure, which was drawn as a perspective view so as to show the arrangement of the inspection mark structure. Further, FIG. 18B is a plan view schematically showing the inspection mark structure of FIG. 18A.

As shown in each figure, a multilayered circuit substrate 100 is made up by laminating, through a circuit electrode 102, a plurality of layers of substrates having a via hole 101 formed by filling a through hole in the thickness direction with a conductive material. The via hole 101 in each substrate is connected with the circuit electrode 102, to internally form an electric circuit.

Further, other than the via hole 101, inspection via holes 103, 104, 105, 106, 107 as inspection marks for inspecting the lamination matching precision are arranged in the substrates in such positions not to overlap each other as seen from the lamination direction shown in FIG. 18B, and these inspection via holes constitute an inspection mark structure 110.

In the lamination matching precision inspection, the inspection mark structure 110 in the multilayered circuit substrate 100 is observed from the lamination direction of FIG. 18B, using the X-ray transmission device. When the shape of the inspection mark structure is observed to be warped from the shape at the time of lamination, it is determined that displacement has occurred. Further, the warped shape of the inspection mark structure is observed, to determine a direction of displacement of the displaced substrate and a displacement amount so as to discriminate between the normal and defective states of the multilayered circuit substrate 100.

### SUMMARY OF THE INVENTION

However, there have been problems with the lamination matching precision inspection using the foregoing conventional inspection mark structure, as described below.

In the conventional lamination matching precision inspection, the X-ray transmission device is used, but since determination of displacement is ultimately made based upon visual inspection of an inspector, there is the risk of erroneously recognizing the occurrence or place of displacement. Further, there is also the risk of erroneous recognition in determining a size of a displacement amount, and the like.

The present invention was made for considering the problems as thus described, and has an object to provide an inspection-mark structure, a substrate sheet laminate, a multilayered circuit substrate, a method for inspecting lamination matching precision of a multilayered circuit substrate, and a method for designing a substrate sheet laminate, which allow objective inspection on lamination matching precision.

The 1^{st} aspect of the present invention is an inspection mark structure, comprising:

an inspection via hole, which is provided in any of substrate sheets constituting at least two layers of substrate sheet laminates;

a round pattern electrode, which is formed on one face side of said substrate sheet provided with said inspection via hole, and provided around the end face of said inspection via hole at such a predetermined distance as not to come into contact with said end face; and

a conduction electrode, which is formed on the other face side of said substrate sheet provided with said inspection via hole, and provided so as to be electrically connected with the end face of said inspection via hole.

The 2^{nd} aspect of the present invention is the inspection mark structure according to the 1^{st} aspect of the present invention, wherein said round pattern electrode has a shape of continuously surrounding said end face of said inspection via hole.

The 3^{rd} aspect of the present invention is the inspection mark structure according to the 2^{nd} aspect of the present invention, wherein the shape of continuously surrounding said end face of said inspection via hole is similar to the shape of said end face of said inspection via hole.

The 4^{th} aspect of the present invention is the inspection mark structure according to the 2^{nd} aspect of the present invention, wherein the shape of continuously surrounding said end face of said inspection via hole is not similar to the shape of said end face of said inspection via hole.

The 5^{th} aspect of the present invention is the inspection mark structure according to the 1^{st} aspect of the present invention, wherein said round pattern electrode has the shape of surrounding, with cuts, said end face of said inspection via hole.

The 6^{th} aspect of the present invention is the inspection mark structure according to the 5^{th} aspect of the present invention, wherein said round pattern electrode is made up of a plurality of sub-pattern electrodes provided around the end face of said inspection via hole.

The 7^{th} aspect of the present invention is the inspection mark structure according to the 6^{th} aspect of the present invention, wherein said sub-pattern electrode is arranged point-symmetrically with the end face of said inspection via hole.

The 8^{th} aspect of the present invention is the inspection mark structure according to the 7^{th} aspect of the present invention, wherein two or four of said sub-pattern electrodes having an identical shape are evenly spaced around the end face of said inspection via hole.

The 9^{th} aspect of the present invention is an inspection mark structure group, comprising a plurality of inspection mark structures according to the 1^{st} aspect of the present invention,

wherein said predetermined distance between said round pattern electrode and said inspection via hole varies in each or part of said inspection mark structures.

The 10^{th} aspect of the present invention is an inspection mark structure group, comprising a plurality of inspection mark structures according to the 4^{th} aspect of the present invention, wherein

said shape of continuously surrounding the end face of said inspection via hole in said round pattern electrode in each inspection mark structure is identical, and

arrangements of said shapes do not match one another.

The 11^{th} aspect of the present invention is the inspection mark structure group according to the 10^{th} aspect of the present invention, wherein,

in each of said inspection mark structures,

the shape of said end face of said inspection via hole is circular,

said shape of continuously surrounding said end face of said inspection via hole in said round pattern electrode is oblong or elliptic and said oblong or elliptic shapes are orthogonal to each other.

The 12^{th} aspect of the present invention is a substrate sheet laminate, comprising:

a circuit electrode provided on a substrate sheet having a via hole; and

an inspection mark structure according to the 1^{st} aspect of the present invention formed on said substrate sheet.

The 13^{th} aspect of the present invention The substrate sheet laminate according to the 12^{th} aspect of the present invention, wherein

said inspection mark structures are provided in a plurality of numbers,

the shape of continuously surrounding said end face of said inspection via hole in said round pattern electrode in said inspection mark structure is not similar to the shape of said end face of said inspection via hole,

said shape continuously surrounding said end face of said inspection via hole in said round pattern electrode in each inspection mark structure is identical, and

arrangements of said shapes do not match each other.

The 14^{th} aspect of the present invention is a multilayered circuit substrate, formed by performing heat-pressing on a substrate sheet laminate according to the 12th aspect of the present invention.

The 15^{th} aspect of the present invention is an inspection mark structure, comprising:

an inspection via hole, which is provided in any of substrate sheets constituting at least two layers of substrate sheet laminates;

a round pattern electrode, which is formed on one face side of said substrate sheet provided with said inspection via hole, and provided around the end face of said inspection via hole so as to come into contact with said end face; and

a conduction electrode, which is formed on the other face side of said substrate sheet provided with said inspection via hole, and provided so as to be electrically connected with the end face of said inspection via hole.

The 16^{th} aspect of the present invention is the inspection mark structure according to the 15^{th} aspect of the present invention, wherein said round pattern electrode is provided around the end face of said inspection via hole, and made up of a plurality of sub-pattern electrodes each in contact with said end face.

The 17^{th} aspect of the present invention is the inspection mark structure according to the 16^{th} aspect of the present invention, wherein said sub-pattern electrode is arranged point-symmetrically with the end face of said inspection via hole.

The 18^{th} aspect of the present invention is an inspection mark structure group, comprising a plurality of inspection mark structures according to the 15^{th} aspect of the present invention,

wherein the outer diameter of the end face of said inspection via hole varies in each or part of said inspection mark structures.

The 19^{th} aspect of the present invention is a substrate sheet laminate, comprising:

a plurality of substrate sheets having a via hole;

a circuit electrode provided on said plurality of substrate sheet layers; and

an inspection mark structure according to the 15^{th} aspect of the present invention formed on said plurality of substrate sheet layers.

The 20^{th} aspect of the present invention is the substrate sheet laminate according to the 19^{th} aspect of the present invention, wherein

said inspection mark structures are provided in a plurality of numbers, and

a size of a contacting portion of the end face of said inspection via hole and said round pattern electrode in said inspection mark structure varies in each or part of a plurality of said inspection mark structures.

The 21^{st} aspect of the present invention is a multilayered circuit substrate, formed by performing heat-pressing on a substrate sheet laminate according to the 18^{th} aspect of the present invention.

The 22^{nd} aspect of the present invention is a method for inspecting lamination matching precision of a multilayered circuit substrate having:

a plurality of substrate sheets having a via hole;

a circuit electrode provided on said plurality of substrate sheet layers; and

an inspection mark structure formed on said plurality of substrate sheet layers, said structure including an inspection via hole which is provided in any of substrate sheets constituting at least two layers of substrate sheet laminates, a round pattern electrode which is formed on one face side of said substrate sheet provided with said inspection via hole and provided around the end face of said inspection via hole at such a predetermined distance as not to come into contact with said end face or so as to come into contact with said end face, and a conduction electrode which is formed on the other face side of said substrate sheet provided with said inspection via hole and provided so as to be electrically connected with the end face of said inspection via hole,

said method comprising the steps of:

electrically connecting said conduction electrode and said round pattern electrode in said inspection mark structure; and

determining that said lamination matching precision is held (A) when conduction does not occur by said connection in the case of said inspection mark structure having said round pattern electrode provided around the end face of said inspection via hole at such a predetermined distance as not to come into contact with said end face, or (B) when conduction occurs by said connection in the case of said inspection mark structure having said round pattern electrode provided around the end face of said inspection via hole so as to come into contact with said end face.

The 23^{rd} aspect of the present invention is the method for inspecting lamination matching precision of a multilayered circuit substrate according to the 22^{nd} aspect of the present invention, wherein said lamination matching precision is at least one of occurrence or non-occurrence of displacement between substrates constituting said multilayered circuit substrate, and a direction and a size of the displacement.

The 24^{th} aspect of the present invention is a method for designing a substrate sheet laminate, comprising the steps of:

forming a testing substrate sheet laminate by laminating said plurality of substrate sheets where an inspection mark structure is formed such that a circuit electrode is located between layers of the substrate sheet, said inspection mark structure having an inspection via hole which is provided in any of substrate sheets constituting at least two layers of substrate sheet laminates formed in a plurality of substrate sheets having a via hole in a predetermined design condition, a round pattern electrode which is formed on one face side of said substrate sheet provided with said inspection via hole and provided around the end face of said inspection via hole at such a predetermined distance as not to come into contact with said end face or so as to come into contact with said end face, and a conduction electrode which is formed on the other face side of said substrate sheet provided with said inspection via hole and provided so as to be electrically connected with the end face of said inspection via hole;

performing heat-pressing on said testing substrate sheet laminate, to form a testing multilayered circuit substrate;

acquiring a direction or a size of displacement of said substrate as said lamination matching precision of said testing multilayered circuit substrate by the use of a method for inspecting lamination matching precision of a multilayered circuit substrate according to the 22^{nd} aspect of the present invention; and

correcting said predetermined design condition by the use of the acquired direction or size of displacement of said substrate.

The 25^{th} aspect of the present invention is the method for designing a substrate sheet laminate according to the 24^{th} aspect of the present invention, wherein said predetermined design condition is a position of lamination of each of said plurality of substrate sheets.

According to the present invention, it is possible to provide an inspection mark structure, a substrate sheet laminate, a multilayered circuit substrate, a method for inspecting lamination matching precision of a multilayered circuit substrate, and a method for designing a substrate sheet laminate, which allow objective inspection on lamination matching precision.

### BRIEF DESCRIPTION OF THE DRAWINGS

FIG. 1A is a view schematically showing a configuration of an inspection mark structure of a multilayered circuit substrate according to Embodiment 1 of the present invention, and FIG. 1B is an expanded view schematically showing a main part of FIG. 1A;

FIG. 2A is a schematic plan view of an inspection mark structure 1, and FIG. 2B is a schematic sectional view along a line A-A′ of FIG. 2A;

FIG. 3A is a view for explaining a principle of a method for inspecting lamination matching precision of the multilayered circuit substrate according to Embodiment 1 of the present invention, and FIG. 3B is a view for explaining the principle of the method for inspecting lamination matching precision of the multilayered circuit substrate according to Embodiment 1 of the present invention;

FIG. 4 is a plan view showing an example of a substrate sheet laminate 10;

FIG. 5A is a view schematically showing a configuration of an inspection mark structure group of a multilayered circuit substrate according to Embodiment 2 of the present invention, and FIG. 5B is a schematic sectional view along a line A-A′ of FIG. 5A;

FIG. 6A is a view schematically showing another constitutional example of the inspection mark structure group of the multilayered circuit substrate according to Embodiment 2 of the present invention, and FIG. 6B is a schematic sectional view along a line A-A′ of FIG. 6A;

FIG. 7A is a view schematically showing a configuration of an inspection mark structure of a multilayered circuit substrate according to Embodiment 3 of the present invention, and FIG. 7B is a schematic sectional view along a line A-A′ of FIG. 7A;

FIG. 8 is an expanded view schematically showing a main part of the inspection mark structure of the multilayered circuit substrate according to Embodiment 3 of the present invention;

FIG. 9A is a view schematically showing another constitutional example of the inspection mark structure of the multilayered circuit substrate according to Embodiment 3 of the present invention, and FIG. 9B is a schematic sectional view along a line A-A′ of FIG. 9A;

FIG. 10A is a view schematically showing another constitutional example of the inspection mark structure of the multilayered circuit substrate according to Embodiment 3 of the present invention, and FIG. 10B is a schematic sectional view along a line A-A′ of FIG. 10A;

FIG. 11A is a view schematically showing a configuration of an inspection mark structure group of a multilayered circuit substrate according to Embodiment 4 of the present invention, and FIG. 11B is a schematic sectional view along a line A-A′ of FIG. 11A;

FIG. 12A is a view schematically showing a configuration of an inspection mark structure of a multilayered circuit substrate according to Embodiment 5 of the present invention, and FIG. 12B is a schematic sectional view along a line A-A′ of FIG. 12A;

FIG. 13 is an expanded view schematically showing a main part of the inspection mark structure of the multilayered circuit substrate according to Embodiment 5 of the present invention;

FIG. 14A is a view schematically showing an explanation of an inspection by means of the inspection mark structure of the multilayered circuit substrate according to Embodiment 5 of the present invention, FIG. 14B is a view schematically showing the explanation of the inspection by means of the inspection mark structure of the multilayered circuit substrate according to Embodiment 5; FIG. 14C is a view schematically showing the explanation of the inspection by means of the inspection mark structure of the multilayered circuit substrate according to Embodiment 5; and FIG. 14D is a view schematically showing the explanation of the inspection by means of the inspection mark structure of the multilayered circuit substrate according to Embodiment 5;

FIG. 15 is a view schematically showing another constitutional example of the inspection mark structure of the multilayered circuit substrate according to Embodiment 5 of the present invention;

FIG. 16 is a view showing a flowchart for explaining a method for manufacturing a multilayered circuit substrate according to Embodiment 6 of the present invention;

FIG. 17 is a view showing another constitutional example of a round pattern electrode 1b in the inspection mark structure of the multilayered circuit substrate according to Embodiment 1 of the present invention; and

FIG. 18A is a view showing a multilayered circuit substrate formed by performing heat pressing on a substrate sheet laminate provided with a conventional inspection mark structure; and FIG. 18B is a plan view schematically showing the conventional inspection mark structure.

### DESCRIPTION OF SYMBOLS

1, 50a, 50b, 51a, 51b, 70 to 72, 80 to 83, 90 Inspection mark structure
1a Inspection via hole
1b, 1b′ Round pattern electrode
1c, 1c′ Conduction electrode
1e, 1e′ Opening
1f End face
2a, 4a, 5 Wire
2b Galvanometer
3a to 3d, 6a, 6b, 7a, 7b, 8a to 8d, 8e to 8h Sub-pattern electrode
10 Substrate sheet laminate
11a to 11e Substrate sheet
12 Electric circuit
40, 41 Boundary
42a, 42b, 43a, 43b Position
101 Via hole
102 Circuit electrode

### PREFERRED EMBODIMENTS OF THE INVENTION

In the following, embodiments of the present invention are described with reference to drawings.

### Embodiment 1

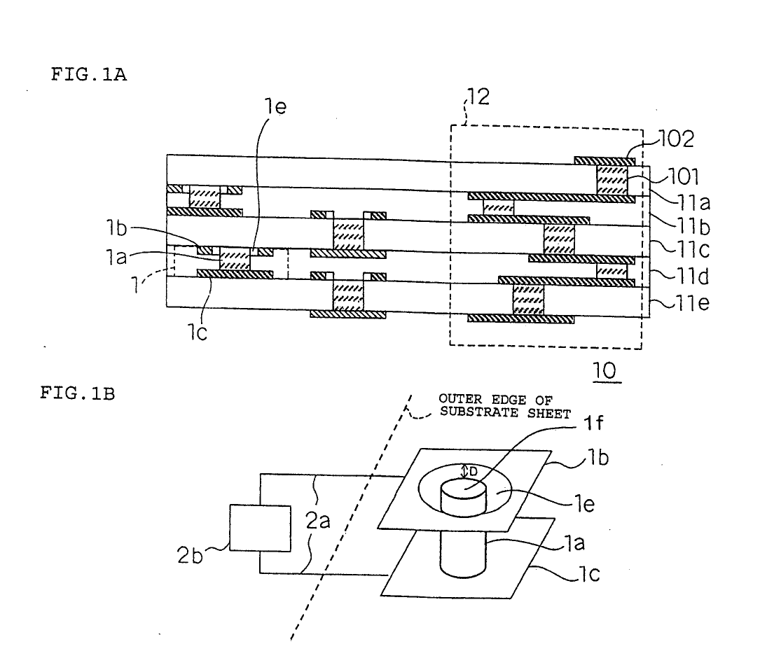

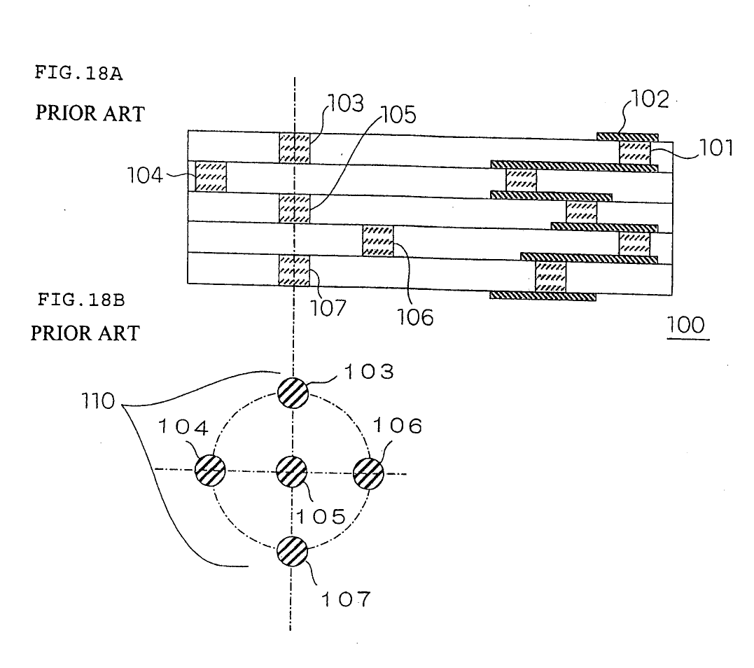

FIG. 1A is a view schematically showing a configuration of an inspection mark structure of a multilayered circuit substrate according to Embodiment 1 of the present invention, and FIG. 1B is an expanded view schematically showing a main part of FIG. 1A. However, sections identical with or corresponding to those in FIG. 18A are provided with the same symbols/numerals.

As shown in FIG. 1, the inspection mark structure of the multilayered circuit substrate of the present embodiment is provided in a substrate sheet laminate 10 before subjected to heat-pressing for completion.

The substrate sheet laminate 10 is formed by laminating substrate sheets 11a to 11e. A via hole 101 is provide in each of the substrate sheets, and a circuit electrode 102 constituting an internal circuit is arranged between the substrate sheet layers. The via hole 101 in each substrate is connected to the circuit electrode 102, to internally form an electric circuit 12.

Next, the inspection mark structure is described by taking as an example an inspection mark structure 1 formed between the substrate sheets 11a and 11d shown in FIG. 1A. As shown in FIG. 1A, the inspection mark structures 1 is made up of an inspection via hole 1a provided inside the substrate sheet 11d, a round pattern electrode 1b and a conduction electrode 1c which are respectively provided on both main faces of the substrate sheet 11d. It is to be noted that each electrode constituting the inspection mark structure 1 and each electrode constituting the electric circuit 12 are formed in the same patterning on each face of the substrate sheets 11a to 11e.

The conduction electrode 1c has a flat shape as well as a square outer shape, and is in contact with the end face 1f of the inspection via hole 1a.

Meanwhile, as shown in FIG. 1B, the round pattern electrode 1b has the same flat shape as the conduction electrode, and is formed on the side of the main faces of the substrate sheet 11d where the conduction electrode 1c is not formed. An opening 1e is further provided at the center, and an end face 1f of the inspection via hole 1a is located inside the opening 1e, and arranged so as not to come into contact with an electrode portion.

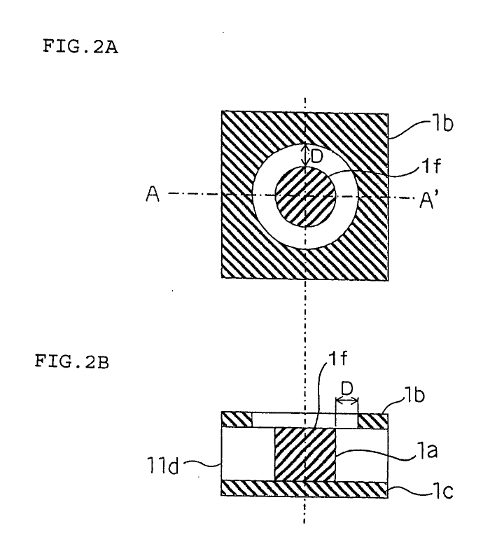

Next, FIG. 2A shows a schematic plan view of the inspection mark structure 1, and FIG. 2A shows a schematic sectional view along a line A-A′ of FIG. 2A. As shown in FIG. 2A, the shapes of the end face 1f of the inspection via hole 1a and the opening 1e of the round pattern electrode 1b are located in the concentric circles form, and a spacing of an equidistance D is formed between the inspection via hole 1a and the round pattern electrode 1b. Here, a reversed shape of the electrode used for the circuit electrode 102 is typically used as the shape of the opening 1e.

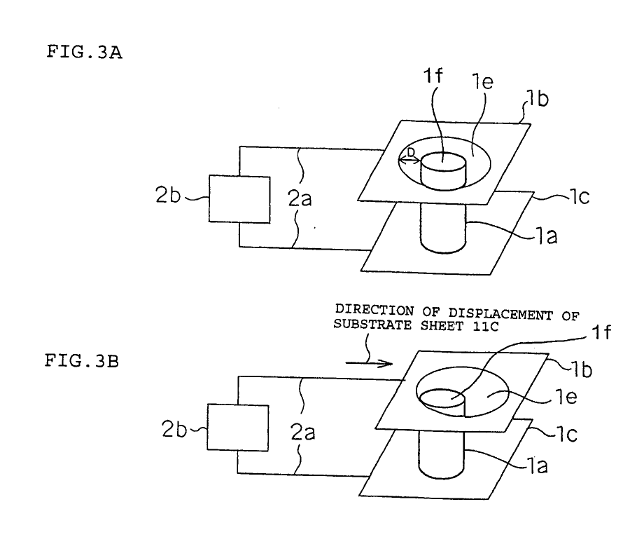

Meanwhile, as shown in FIG. 1B, the round pattern electrode 1b and the conduction electrode 1c are each provided with a wire 2a that is pulled out to the outside of the substrate sheet laminate 10. The wire 2a is used for connection to a galvanometer in the substrate sheet laminate 10 in a completed state as the multilayered circuit substrate after heat-pressing. A principle of a method for inspecting lamination matching precision of the multilayered circuit substrate using the inspection mark structure of the multilayered circuit substrate of the present embodiment having the configuration as described above is described below with reference to FIGS. 3A and 3B.

As described in the section describing the prior art, a plurality of substrate sheets are laminated such that the circuit electrode 102 are arranged at a predetermined position between the layers to form the substrate sheet laminate, which is subjected to heat-pressing to complete the multilayered circuit substrate. However, when displacement occurs between the substrate sheets during heat-pressing, it brings about contact failure between the circuit electrodes 102, to cause the electric circuit 12 to be defective.

In the inspection mark structure of the multilayered circuit substrate of the present embodiment, as shown in FIG. 3A, in a state where the substrate sheet laminate 10 has been formed, the end face 1f of the inspection via hole 1a and the round pattern electrode 1b are arranged so as not come into each other with the spacing of the distance D between the substrate sheets 11c and 11d.

Next, when displacement occurs between the substrate sheets in completing the multilayered circuit substrate by heat-pressing, the inspection via hole 1a buried inside the substrate sheet 11d shifts associated with the shift of the substrate sheet 11d (it does not shift with respect to the substrate sheet 11d), but the round pattern electrode 1b located between the substrate sheets 11c and 11d shifts as drawn by displacement of the substrate sheet 11c or 11d.

At this time, when the shifting distance exceeds the distance D between the opening 1e and the end face 1f of the inspection via hole 1a, as shown in FIG. 3B, the end face 1f of the inspection via hole 1a and the round pattern electrode 1b come into contact with each other. It is to be noted that in FIG. 3B, the substrate sheet 11c is displaced from its original position.

Therefore, the wire 2a of the completed multilayered circuit substrate is connected with a galvanometer 2b to inspect the occurrence or non-occurrence of conduction so that the occurrence or non-occurrence of displacement can be determined. Namely, as shown in FIG. 3A, in a case where displacement does not occur, conduction does not occur in a conduction circuit made up of the wire 2a, the round pattern electrode 1b, the inspection via hole 1a, and the conduction electrode 1c even when connected with the galvanometer 2b since the end face 1f of the inspection via hole 1a and the round pattern electrode 1b are not in contact with each other.

On the other hand, when the end face 1f of the inspection via hole 1a and the round pattern electrode 1b come into contact with each other due to displacement between the substrate sheets, the conduction circuit is completed, and conduction can be recognized when the conduction circuit is connected with the galvanometer 2b.

As thus described, through the use of the inspection mark structure of the present embodiment, erroneous recognition based upon visual inspection or the like can be removed, so as to implement a method for inspecting lamination matching precision of the multilayered circuit substrate in which the occurrence or non-occurrence of displacement can be objectively determined.

Here, a permissible degree of displacement is set based upon the distance D between the opening 1e and the end face 1f of the inspection via hole 1a. The shape of the opening 1e is set as a reversed shape of the round electrode of the circuit electrode 102, and thereby the occurrence or non-occurrence of displacement detected by the galvanometer is detected as the occurrence or non-occurrence of aberration from the permissible limit of design error of the electric circuit 12.

Accordingly, by changing the size of the opening 1e or the size of the inspection via hole 1a to adjust the distance D, it is possible to execute, on the basis of objective determination, an inspection based upon lamination matching precision in accordance with the number of laminated substrates, miniaturization of a circuit pattern or the like in a required multilayered circuit substrate.

Next, an arrangement of the inspection mark structure on the substrate sheet laminate 10 is described.

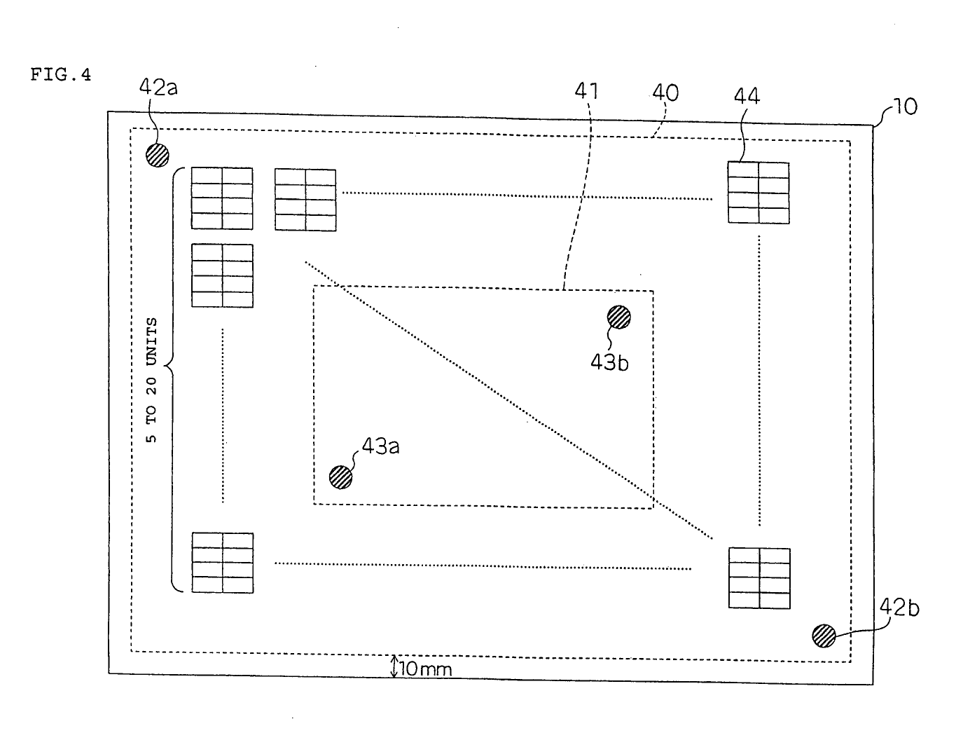

FIG. 4 is a plan view showing an example of the substrate sheet laminate 10. In FIG. 4, the substrate sheet laminate 10 is designed so as to arrange a substrate unit 44 having eight multilayered circuit substrates as one unit in matrix shape within a rectangular boundary 40 that sets an excess region after heat-pressing. The electric circuit 12 is formed inside the substrate sheet laminate 10 in accordance with each multilayered circuit substrate. The inspection mark structures are internally formed so as to be at least located positions 42a and 42b on a diagonal line within the boundary 40. Displacement of the substrate sheet laminate 10 tends to appear at the edge, and providing the inspection mark structures in positions on mutually close conditions can lead to an increase in detection precision.

Further, the inspection mark structures may be provided in positions 43a and 43b on a diagonal line within a boundary 41 that is inside the boundary 40 in the figure. When an expansion coefficient at a position on the flat face of the substrate sheet due to heat-pressing, or the like, differs between on the boundary 40 close to the edge and on the boundary 41 close to the center in the whole of the substrate sheet laminate 10, an inspection result may differ between at the position 42a (42b) and at the position. 43a (43b), but such a difference can be easily detected.

Moreover, the inspection mark structure may be configured to be provided in each substrate unit 44, and may further be provided on individual multilayered circuit substrates that are cut out from the substrate unit 44. In this case, the inspection can be performed in the unit of the substrate unit or the unit of the multilayered circuit substrate. Furthermore, the inspection mark structure itself may be used as an identifier of a product.

Further, in the example shown in FIG. 1A, in order to correspond to patterning of the circuit electrode 102, the inspection via holes 1a and the round pattern electrodes 1b in the inspection mark structures are divided into those provided on the same substrate sheet and those provided respectively on the opposing substrate sheets prior to lamination.

However, in the substrate sheet laminate after lamination, the round pattern electrode is certainly arranged between the layers, and it can be considered that an influence of displacement due to heat-pressing is generated independently of the arrangement relation between the inspection via hole 1a and the round pattern electrode 1b in the substrate sheets prior to lamination. Although the inspection via hole 1a was formed on the substrate sheet 11d and the round pattern electrode 1b was formed on the substrate sheet 11c in the inspection mark structure 1 in the present embodiment, even in a configuration where an inspection via hole 1a and a round pattern electrode 1b which are adjacent to the above-mentioned inspection via hole 1a and round pattern electrode 1b are formed on the one substrate sheet 11c, the same effect of the present embodiment can be obtained.

### Embodiment 2

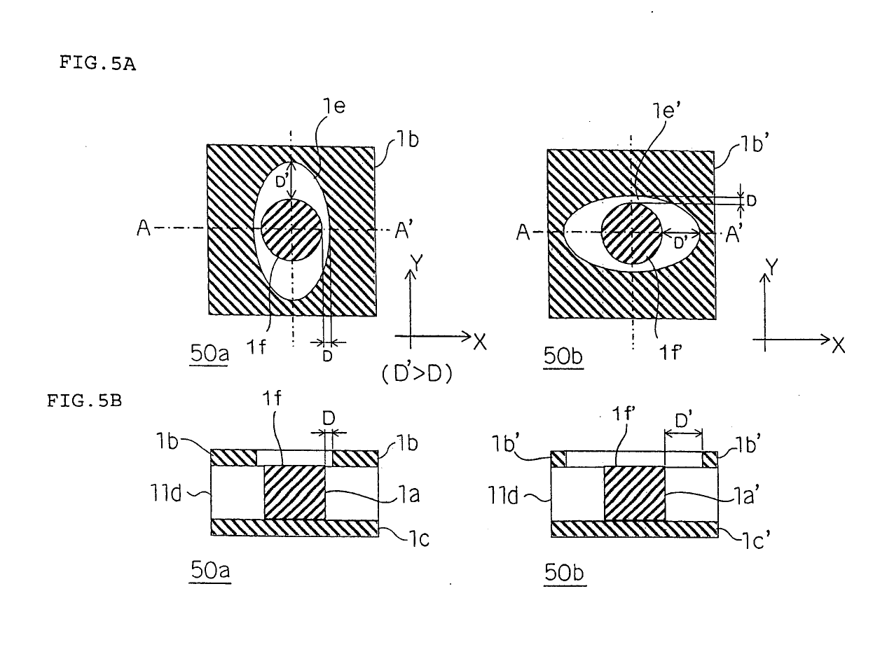

FIG. 5A is a schematic plan view of an inspection mark structure group of a multilayered circuit substrate according to Embodiment 2 of the present invention, and FIG. 5B is a schematic sectional view along a line A-A′ of FIG. 5A.

As shown in the figures, in the present embodiment, the inspection mark structure group is formed such that a pair of inspection mark structures 50a and 50b having the shapes of mutually orthogonal ellipses is provided as the shapes of the opening 1e of the round pattern electrode 1b on the one substrate sheet 11d.

In the following, a specific description is given.

A shown in FIG. 5A, in the inspection mark structure 50a, the opening 1e of the round pattern electrode 1b had an elliptical shape with its long axis extending in the Y-axis direction in the figure, and a distance between the end face 1f of the inspection via hole 1a and the round pattern electrode 1b was the distance D on the long axis side as in Embodiment 1, and was a distance D′, which is longer than the distance D, on the short axis side.

Further, in the inspection mark structure 50b, the opening 1e′ of the round pattern electrode 1b′ had an elliptical shape with its short axis extending in the Y-axis direction in the figure, and a distance between the end face 1f′ of the inspection via hole 1a′ and the round pattern electrode 1b′ was the distance D on the short axis side as in Embodiment 1, and was the distance D′ on the long axis side.

It is to be noted that the opening 1e and 1e′ are identical in size except for the arrangement thereof in the round pattern electrode. Further, the round pattern electrodes 1b and 1b′, as well as the conduction electrode 1c and 1c′, are identical in size. Further, in the inspection mark structures, wires are individually pulled out (not shown) so that conduction can be checked.

Thereby, the following effect can be obtained. Namely, when displacement occurs between the substrate sheets, a distance of the end face differs between in the X-axis and Y-axis directions in the figure which correspond to the long axis side and short axis side of the ellipse shape of each opening with respect to the shift of the round pattern electrode 1b and the round pattern electrode 1b′, and hence the degree of precision in detecting displacement also differs between in the X-axis and Y-axis directions.

Therefore, the substrate sheet laminate 10 having a pair of inspection mark structures 50a, 50b of FIG. 5 is formed as the inspection mark structure group, which is then subjected to heat-pressing to complete the multilayered circuit substrate, and thereafter, conduction is checked individually for the inspection mark structure 50a, 50b, so that the direction of displacement can be objectively determined.

There are four kinds of checking results as follows: (1) conduction is recognized neither in the inspection mark structures 50a, 50b; (2) conduction is recognized only in the inspection mark structure 50a; (3) conduction is recognized only in the inspection mark structure 50b; and (4) conduction are recognized both in the inspection mark structures 50a, 50b.

From the checking result of (2) among the above, it is possible to determine that displacement of the substrate sheet 11d has occurred in the X-axis direction in the figure. Further, from the checking result of (3), it is possible to determine that displacement of the substrate sheet 11d has occurred in the Y-axis direction in the figure. It is to be noted that the checking result of (1) shows that no displacement has occurred, and the checking result of (4) shows displacement has occurred far beyond a permissible limit both in the X-axis and the Y-axis in the figure.

As thus described, according to the inspection mark structure group of the present embodiment, it is possible to objectively determine the direction of displacement other than the occurrence or non-occurrence of displacement.

In addition, although the shape of the opening 1e(1e′) was elliptical in the above-mentioned configuration, it may be oblong, namely the shape formed by connecting mutually opposing semicircles with lines, or the shape of a “koban”, Japanese old coin in elliptical shape. It may also be rectangular. In brief, the same effect as in the configuration of FIG. 5 can be obtained so long as the shape of the opening is formed such that in the configuration of a pair of the inspection mark structures, the distance between the inspection via hole and the round pattern electrode differs between in the two mutually orthogonal directions, and the directions of those different distances differ.

Further, the differences in distance between the end face 1f(1f′) of the inspection via hole 1a and the round pattern electrode 1b(1b′) in the opening 1e(1e′) are not restricted to the two orthogonal directions.

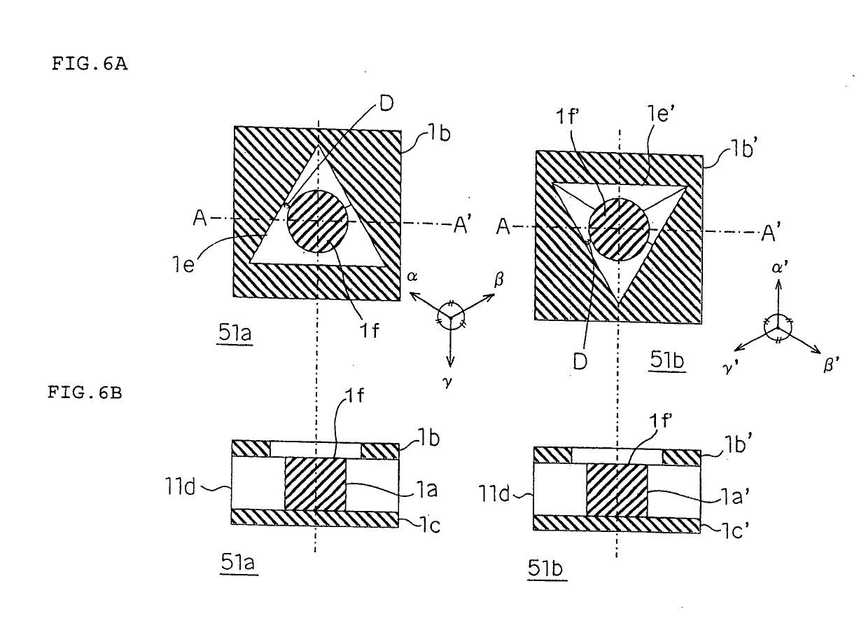

FIGS. 6A and 6B are views showing another configuration of the inspection mark structure group of the present embodiment. As shown in FIG. 6A, a pair of inspection mark structures 51a, 51b, having the round pattern electrodes 1b, 1b′ respectively provided with the openings 1e and 1c′ in regular triangle shape in different orientations, are formed so that it is possible to determine whether displacement between the substrate sheets has occurred in a three-axis direction described with a coordinate (α, β, γ) in FIG. 6A or in a three-axis direction described with a coordinate (α′, ⊖′, γ′).

### Embodiment 3

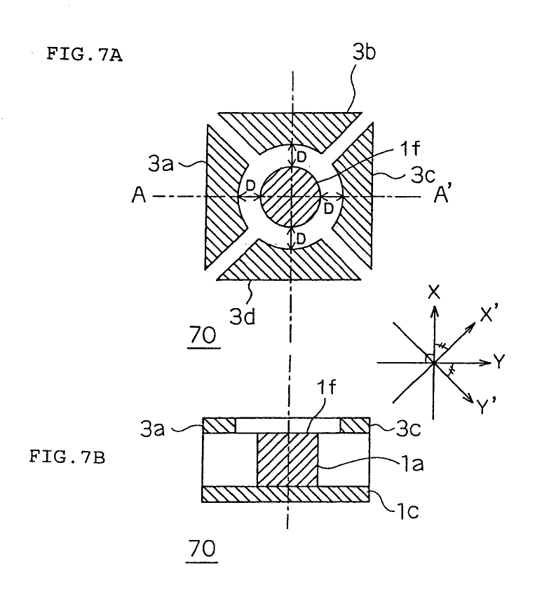

FIG. 7A is a schematic plan view of an inspection mark structure of a multilayered circuit substrate according to Embodiment 3 of the present invention, and FIG. 7B is a schematic sectional view along a line A-A′ of FIG. 7A.

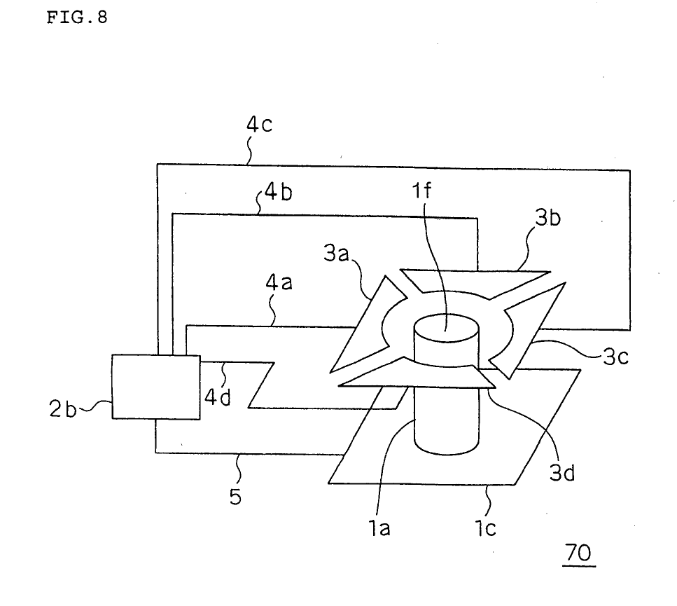

Further, FIG. 8 is an oblique view schematically showing a main part of FIG. 7A. In each figure, sections identical with or corresponding to those in FIGS. 1 and 2 are provided with the same symbols/numerals.

An inspection mark structure 70 according to present Embodiment 3 is characterized in that four sub-pattern electrodes 3a to 3d are provided around the end face 1f of the inspection via hole 1a, in place of the round pattern electrode 1b of Embodiment 1.

As shown in FIG. 7A, although an outer shape formed by the whole of the four electrodes is substantially identical to that of the round pattern electrode 1b, independent electrodes are constituted due to division along diagonal lines of a square shape. Further, the space between each of the sub-pattern electrodes 3a to 3d and the end face 1f of the inspection via hole 1a is an equidistance D.

Further, as shown in FIG. 8, in the inspection mark structure according to present Embodiment 3, the sub-pattern electrodes 3a to 3d are respectively connected to mutually independent wires 4a to 4d. Meanwhile, the inspection via hole 1a and the conduction electrode 1c have the same structures as in Embodiment 1, and one wire 5 is connected from the conduction electrode 1c. The wires 4a to 4d and the wire 5 are connectable to the external galvanometer 2b on the multilayered circuit substrate after heat-pressing has been performed on the substrate sheet laminate.

With the use of the inspection mark structure 70 according to present Embodiment 3 having the configuration as thus described, it is possible to obtain the following effect in the method for inspecting lamination matching precision of a multilayered circuit substrate.

Namely, when displacement occurs between the substrate sheets inside the multilayered circuit substrate and the end face 1f of the inspection via hole 1a comes into contact with any of the sub-pattern electrodes 3a to 3d constituting the round pattern electrode, the galvanometer 2b detects conduction, and since the sub-pattern electrodes 3a to 3d are independent and connected to the galvanometer 2b with the independent wires 4a to 4d, conduction can be checked for each of the sub-pattern electrodes 3a to 3d.

Therefore, previously determining an arrangement place for the sub-pattern electrodes 3a to 3d allows objective determination of the direction of displacement between the substrate sheets from the results of checking conduction for each of the sub-pattern electrodes 3a to 3d.

In the case of the present embodiment, there are three kinds of checking results as follows: (1) conduction is recognized in none of the sub-pattern electrodes 3a to 3d; (2) conduction is recognized in any one of the sub-pattern electrodes 3a to 3d; and (3) conduction is recognized in any one of pairs of adjacent sub-pattern electrodes (3a, 3b), (3b, 3c), (3c, 3d), (3d, 3a) out of the sub-pattern electrode 3a to 3d.

From the checking result of (2) among the above, it is possible to determine that displacement of the substrate sheet 11d has occurred either in the X-axis or Y-axis direction in the figure. As an example, when conduction with the sub-pattern electrode 3a is recognized, it is possible to determine the substrate sheet 11c has shifted in the X-axis downward direction in the figure.

Further, from the checking result of (3), it is possible to determine that displacement of the substrate sheet 11d has occurred either in the X′-axis or Y′-axis direction in the figure, which is a direction rotated at 45 degrees from the X-axis or Y-axis direction in the figure. As an example, when conduction with the sub-pattern electrode (3a, 3b) is recognized, it is possible to determine that the substrate sheet 11c has shifted in the X′-axis downward direction (diagonally left downward on the paper).

As thus described, in the present embodiment, with a configuration formed such that the round pattern electrode as the independent sub-pattern electrodes is arranged around the end face of the inspection via hole, it is possible to objectively determine the direction of displacement other than the occurrence or non-occurrence of displacement.

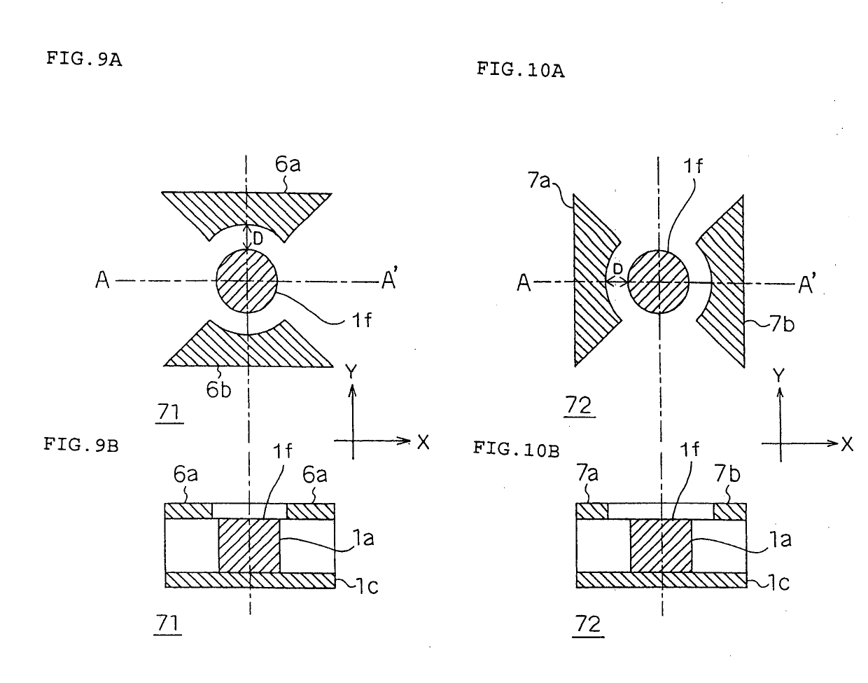

It is to be noted that, although the sub-pattern electrodes 3a to 3d had the shape formed by dividing the square-shaped round pattern electrode into four along the diagonal lines in the above-mentioned configuration, the sub-substrates may have a shape formed by dividing the round pattern electrode into two. FIGS. 9A and 9B show an inspection mark structure 71 in which sub-pattern electrodes 6a and 6b are arranged in the direction parallel to the X-axis in the figure. In this case, recognizing conduction in either of the sub-pattern electrodes 6a and 6b allows determination that displacement of the substrate sheet 11d has occurred in the Y-axis direction in the figure.

Further, FIGS. 10A and 10B show an inspection mark structure 72 where sub-pattern electrodes 7a and 7b are arranged in the direction parallel to the Y-axis in the figure, with dividing positions rotated at 90 degrees from the inspection mark structure 71 of FIG. 9. In this case, recognizing conduction in either of the sub-pattern electrodes 7a and 7b allows determination that displacement of the substrate sheet 11d has occurred in the X-axis direction in the figure.

Further, arranging the inspection mark structures 71, 72 of FIGS. 9 and 10 in parallel between the same substrate sheet layers in the same manner as in Embodiment 2 allows more detailed determination of the direction of displacement as in the configuration of FIG. 7 based upon combination of results of checking conduction in the sub-pattern electrodes.

It is to be noted that although four or two identically shaped sub-pattern electrode were formed around the inspection via hole 1a in the above-mentioned description, the number of sub-pattern electrodes is not restricted thereto. It may be an odd or an arbitrary number not smaller than five in accordance with the direction of displacement wished to be determined. Further, although each of the sub-pattern electrodes had the identical shape, each may have a different shape from one another. Moreover, although the sub-pattern electrodes were configured to be provided point-symmetrically around the inspection via hole 1a, they may be configured to be provided asymmetrically. These variations can be applied at the time of forming the substrate sheet laminate, or in accordance with the arrangement of the inspection mark structure.

### Embodiment 4

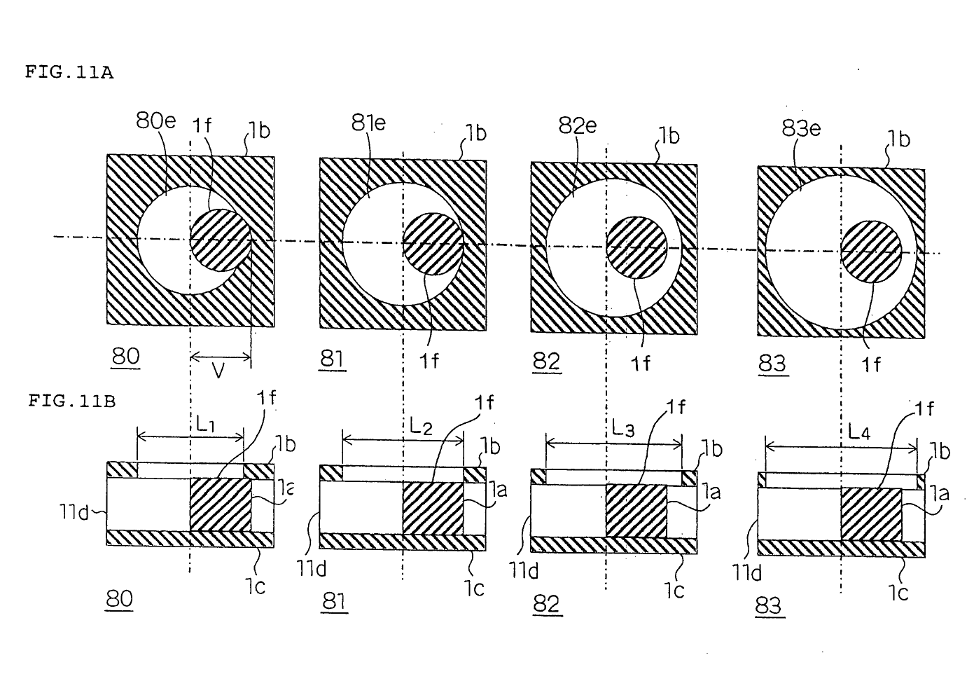

FIGS. 11A and 11B are views showing an inspection mark structure group according to Embodiment 4 of the present invention. In each figure, sections identical with or corresponding to those in FIGS. 1 and 2 are provided with the same symbols/numerals.

The inspection mark structure group has a configuration where a plurality of inspection mark structures 80 to 83 are arranged in parallel between the same substrate sheet layers. In the figure, the inspection mark structures are provided between the substrate sheets 11d and 11c. Further, respective wires are pulled out independently (not shown) from the inspection mark structures so that conduction can be checked.

Further, sections in the inspection mark structures 80 to 83 have an identical shape except for the size of the opening. Diameters L1, L2, L3, L4 of the openings 80e to 83e have the relation of L1<L2<L3<L4.

It is to be noted that the difference between the diameter L1 of the minimum opening 80a and an outer shape V of the inspection via hole 1a is twice as large as the predetermined distance D1 defined in Embodiment 1. Thereby, the opening 80e is defined as having the same size as that of the opening 1e of the inspection mark structure of Embodiment 1 and other openings 81e, 82e, 83e are defined to be larger than the opening 80e. Further, as a specific example, V=130 μm, L1=300 μm, L2=350 μm, L3=400 μm, L4=450 μm, and D=20 μm.

With the use of the inspection mark structure group according to present Embodiment 4, having the above-mentioned configuration, it is possible to obtain the following effect in the method for inspecting lamination matching precision of a multilayered circuit substrate.

Namely, previously setting the sizes of the openings of the inspection mark structures 80 to 83 enables objective determination of the size of displacement between the substrate sheets from the results of checking conduction in the inspection mark structures 80 to 83 through the use of the predetermined distance D showing a permissible displacement limit, and the difference in known sizes of the openings.

In the case of the present embodiment, there are five kinds of checking results as follows: (1) conduction is recognized in none of the inspection mark structures 80 to 83; (2) conduction is recognized only in the inspection mark structure 80; (3) conduction are recognized in the inspection mark structures 80 and 81; (4) conduction are recognized in the inspection mark structures 80 to 82; and (5) conduction are recognized in all of the inspection mark structures 80 to 83. Here, the checking result of (3) corresponds to the example shown in FIG. 11.

From the checking result of (2) among the above, it can be found that the size of displacement of the substrate sheet 11d is within the range of not smaller than 20 μm (=D) and smaller than 50 μm (=L2−L1), the difference between the diameter L2 of the opening 81e of the inspection mark structure 81 and the diameter L1 of the opening 80e of the inspection mark structure 80.

Further, from the checking result of (3), it can be found that the size of displacement of the substrate sheet 11d is within the range of a value not smaller than 50 μm based upon the checking result of (2) above and smaller than 100 μm (=L3−L1), the difference between the diameter L3 of the opening 82e of the inspection mark structure 82 and the diameter L1 of the opening 80e of the inspection mark structure 80.

Further, from the checking result of (4), it can be found that the size of displacement of the substrate sheet 11d is within the range of a value not smaller than 100 μm based upon the checking result of (3) above and smaller than 150 μm (=L4−L1), the difference between the diameter L4 of the opening 83e of the inspection mark structure 83 and the diameter L1 of the opening 80e of the inspection mark structure 80.

As thus described, in the present embodiment, the inspection mark structure group was made up of a plurality of inspection mark structures where a plurality of round pattern electrodes have openings with different diameters, so that the size of displacement can be objectively and quantitatively determined other than the occurrence or non-occurrence of displacement. With the precision of the completed multilayered circuit substrate quantitatively seen, it is possible to more meticulously determine whether the substrate is in a normal or defective state. For example, when manufacturing conditions are made different between a high-density multilayered circuit substrate and a low-density multilayered circuit substrate, such a difference can be used for determining whether the product is in the normal or defective state. Further, since the shape of the opening can be used as it is as the shape of the round electrode, it is possible to quantitatively see an appropriate size of the round electrode of the circuit electrode 102.

In addition, although it was described above that the substrate sheet is displaced isotropically, expansion or shrink of the substrate sheet, which may cause displacement, occurs isotropically at a uniform rate.

Further, although it was described above that the inspection mark structure group is configured to include a plurality of inspection mark structures of Embodiment 1, the inspection mark structure group may include the inspection mark structures of Embodiments 2 or 3 in a plurality of numbers, so long as being configured to have openings with sizes made different individually. In this case, it is possible to objectively determine both the direction and the size of displacement.

Moreover, although the above description was given assuming all the inspection mark structures constituting the inspection mark structure group have openings with different sizes, the sizes of the openings may be made partially different. Providing a plurality of openings with an identical size has the effect of enhancing inspection precision.

### Embodiment 5

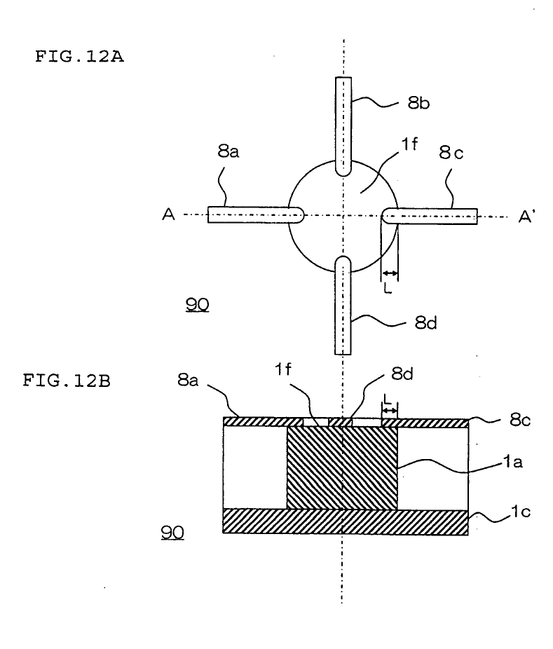

FIG. 12A is a schematic plan view of an inspection mark structure of the multilayered circuit substrate according to Embodiment 5 of the present invention, and FIG. 12B is a schematic sectional view along a line A-A′ of FIG. 12A.

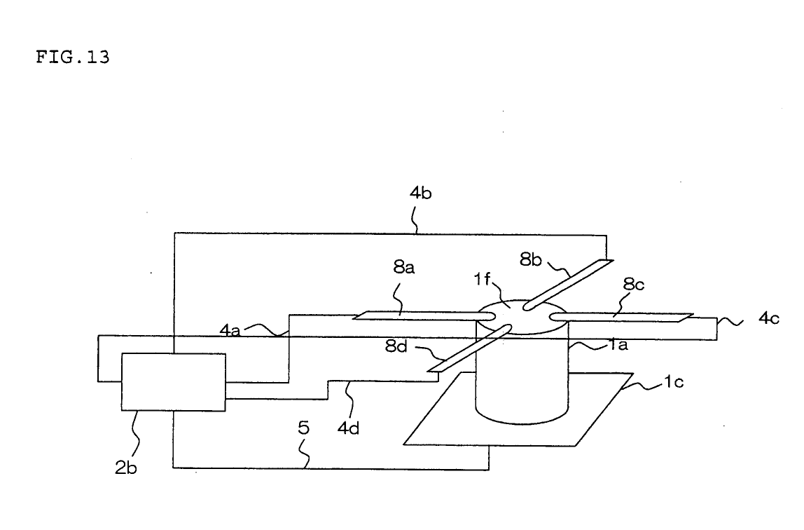

Further, FIG. 13 is an oblique view schematically showing a main part of FIG. 12A. In each figure, sections identical with or corresponding to those in FIGS. 1 and 2 are provided with the same symbols/numerals.

In an inspection mark structure 70 according to present Embodiment 5, four independent square-shaped sub-pattern electrodes 8a to 8d are provided around the end face 1f of the inspection via hole 1a. The sub-pattern electrodes 8a to 8d of present Embodiment 5 are different from Embodiments 1 to 4 in that the edges thereof are configured to be located so as to be in contact with, while overlapping, the end face 1f of the inspection via hole 1a.

As shown in FIG. 13, in the inspection mark structure according to present Embodiment 5, the sub-pattern electrodes 8a to 8d are respectively connected to the independent wires 4a to 4d. Meanwhile, the inspection via hole 1a and the conduction electrode 1c have the same configuration as in Embodiment 1, and the one wire 5 is connected from the conduction electrode 1c. The sub-pattern electrodes 8a to 8d and the wire 5 are connectable to the external galvanometer 2b on the multilayered circuit substrate after heat-pressing has been performed on the substrate sheet laminate.

The method for inspecting lamination matching precision of a multilayered circuit substrate, performed by means of the inspection mark structure 70 according to present Embodiment 5 having the configuration as described above, is a method as described below.

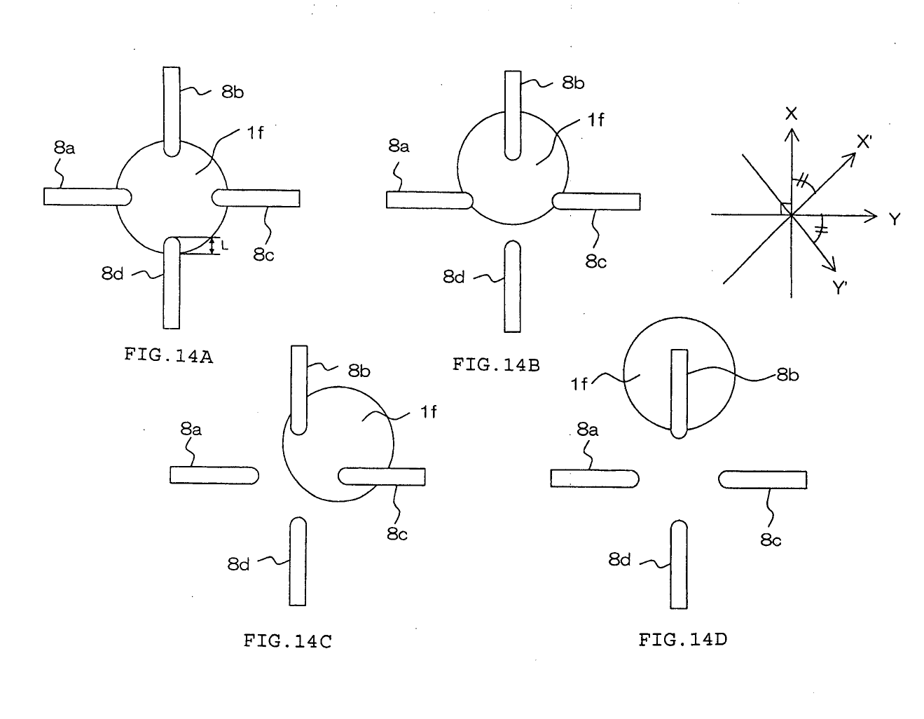

Namely, in the inspection mark structure of the multilayered circuit substrate of the present embodiment, as shown in FIGS. 12 and 14A, in a state where the substrate sheet laminate 10 has been formed, the end face 1f of the inspection via hole 1a and the edges of the sub-pattern electrodes 8a to 8d are arranged in contact with the end face with an overlapping length L between the two substrate sheets. When displacement occurs between the substrate sheets due to heat-pressing, and a displacement amount of the substrate sheets exceeds the overlapping length L, the contact between part or all of the sub-pattern electrodes 8a to 8d and the end face 1f of the inspection via hole 1a is cancelled.

In this case, connecting the wire 2d of the completed multilayered circuit substrate and the galvanometer 2b to inspect the occurrence or non-occurrence of conduction enables determination of the occurrence or non-occurrence of displacement. Namely, as shown in FIG. 14A, when displacement does not occur, the end face 1f of the inspection via hole 1a and all of the sub-pattern electrodes 8a to 8d are in contact with each other in a conduction circuit made up of the wires 4a to 4d, the sub-pattern electrodes 8a to 8d, the inspection via hole 1a and the conduction electrode 1c, and hence conduction is recognized by connection of the galvanometer 2b.

On the other hand, when the contact between the end face 1f of the inspection via hole 1a and the sub-pattern electrodes 8a to 8d is cancelled due to displacement between the substrate sheets, the conduction circuit regarding the sub-pattern electrode whose contact with the end face was cancelled is opened, and no conduction is recognized when the galvanometer 2b is connected. In the case shown by FIG. 14B, since displacement occurs in the X-axis direction in the figure, the contact between the end face 1f of the inspection via hole 1a and the sub-pattern electrode. 8a is cancelled, and hence no conduction is recognized by means of the galvanometer 2b.

As thus described, also with the use of the inspection mark structure in present Embodiment 5, it is possible to eliminate erroneous recognition based upon visual inspection or the like, so as to objectively determine the occurrence or non-occurrence of displacement.

Further, in the present embodiment, as in Embodiment 3, since the sub-pattern electrodes 8a to 8d are independent and connected to the galvanometer 2b through the independent wires 4a to 4d, conduction can be checked for each of the sub-pattern electrodes 8a to 8d. Therefore, previously setting arrangement positions for the sub-pattern electrodes 8a to 8d enables objective determination of the direction of displacement between the substrate sheets from the results of checking conduction for each of the sub-pattern electrodes 3a to 3d.

In the case of the present embodiment, there are five kinds of checking results as follows: (1) conduction are recognized in all of the sub-pattern electrodes 8a to 8d; (2) conduction are recognized in three electrodes except for any one of the sub-pattern electrodes 8a to 8d; (3) conduction is recognized in any of groups consisting of pairs of adjacent sub-pattern electrodes (8a, 8b), (8b, 8c), (8c, 8d), (8d, 8a) out of the sub-pattern electrodes 8a to 8d; and (4) conduction is recognized in any one of the sub-pattern electrodes 8a to 8d.

From the checking result of (2) among the above, it is possible to determine that displacement of the substrate sheet 11d has occurred either in the X-axis or Y-axis direction in the figure. As thus described, the example shown in FIG. 14B is the case where the cutoff of conduction with the sub-pattern electrode 8d has been recognized, and it is possible to determine that the substrate sheet has shifted in the X-axis direction in the figure.

Further, from the checking result of (3), it is possible to determine that displacement of the substrate sheet 11d has occurred either in the X′-axis or Y′-axis direction in the figure, which is a direction rotated at 45 degrees from the X-axis or Y-axis direction in the figure. The example shown in FIG. 14C is the case where the cutoffs of conduction with the sub-pattern electrodes 8a, 8d have been recognized, and it is possible to determine that the substrate sheet has shifted in the X′-axis direction in the figure.

Moreover, from the checking result of (4), it is possible to determine that displacement of the substrate sheet has occurred either in either X-axis or Y-axis direction in the figure, and the displacement amount is larger than in the case of (2) above. The example shown in FIG. 14D is the case where the cutoffs of conduction with the sub-pattern electrodes 8a, 8c, 8d have been recognized, and it is possible to determine that the substrate sheet has shifted in the X-axis direction in the figure and the displacement of the substrate sheet is large in amount.

As thus described, in the present embodiment, a configuration was formed as an inspection mark structure 90 where each edge of the sub-pattern electrodes constituting the independent conduction circuit is arranged around the end face of the inspection via hole in contact with the end face so as to overlap, whereby it is possible to objectively determine the direction of displacement and the degree of size of displacement, other than the occurrence or non-occurrence of displacement.

Further, in the present embodiment, a configuration is formed such that a state where the sub-pattern electrodes 8a to 8d hold conduction with the inspection via hole is a normal state, and thereby an advantage can be obtained as follows. Namely, since the state where conduction can be recognized is the normal state in the conduction inspection using the inspection mark structure 90, it is possible to remove destabilizing factors in determination, like an operational failure of a measuring device such as the galvanometer 2d, so as to perform inspection with higher reliability. Moreover, through the use of the conduction being in the normal state, the inspection via hole 1a and the sub-pattern electrodes 8a to 8d can be used as part of the circuit electrode shown in FIG. 1.

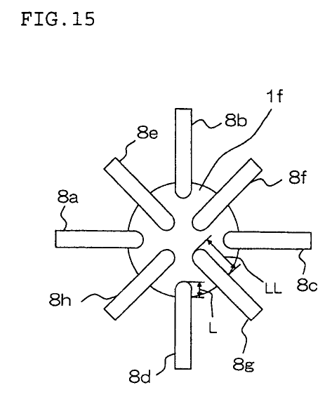

In addition, although in the above configuration, the sub-pattern electrodes 8a to 8d were formed so as to be provided at every equivalent intersecting angle (90 degrees) in four directions around the end face 1f of the inspection via hole 1a, the arrangement position and the number of the sub-pattern electrodes are not restricted thereto. The example shown in FIG. 15 is a configuration with the sub-pattern electrode 8e to 8h added to the sub-pattern electrodes 8a to 8d. The sub-pattern electrode 8e to 8h are a set of four electrodes at the intersecting angles of 90 degrees, having been rotated at 45 degrees from the whole of the sub-pattern electrodes 8a to 8d, and each edge thereof is connected with, while overlapping, the end face if of the inspection via hole 1a with a larger overlapping width LL than the overlapping width L of the sub-pattern electrodes 8a to 8d. With the use of a plurality of sub-pattern electrodes having different overlapping widths and angles, it is possible to enhance displacement detecting precision. Further, the sub-pattern electrode is not restricted by its shape, but may have an arbitrary shape.

Further, although four identically shaped sub-pattern electrodes were formed around the inspection via hole 1a in the above description, the number of sub-pattern electrodes is not restricted thereto. It may be an odd or an arbitrary number not smaller than five in accordance with the direction of displacement wished to be determined. Further, although each sub-pattern electrode had the identical shape, each may have a different shape from one another. Moreover, although the sub-pattern electrodes were configured to be provided point-symmetrically around the inspection via hole 1a, they may be configured to be provided asymmetrically. These variations can be applied at the time of forming the substrate sheet laminate, or in accordance with the arrangement of the inspection mark structure. Further, the variation can be implemented to form an inspection mark structure group as a combination of inspection mark structures having sub-pattern electrodes arranged at different angles, as in the configuration shown in FIG. 9 of Embodiment 3. Moreover, the variation can be implemented to form an inspection mark structure group as a combination of inspection mark structures having different lengths of overlap between the end face 1f of the inspection via hole 1a and the sub-pattern electrodes.

### Embodiment 6

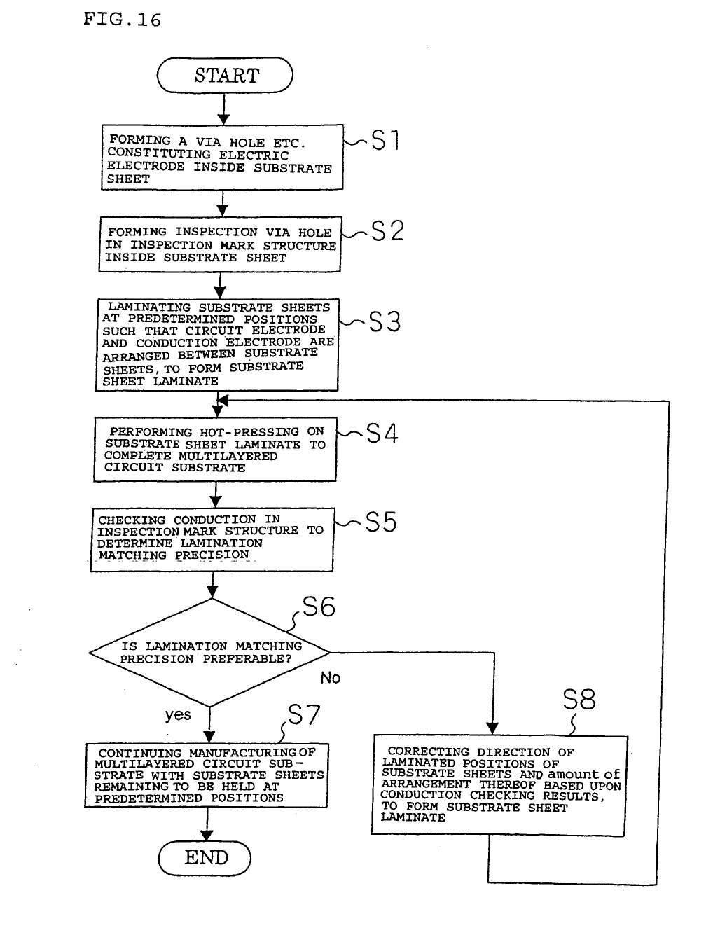

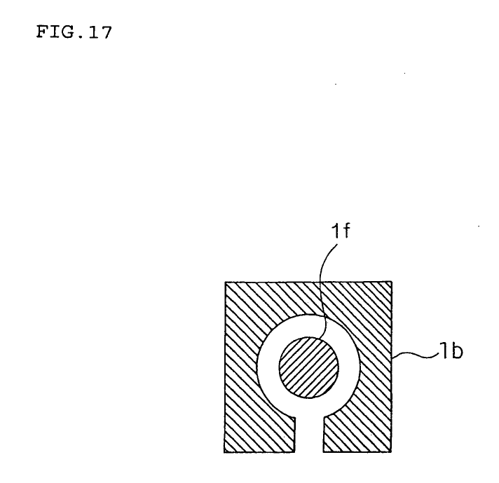

As Embodiment 6 of the present invention, a method for manufacturing a multilayered circuit substrate using an inspection method by means of the inspection mark structure or the inspection mark structure group according to the embodiments of the present invention described above is described with reference to a flowchart of FIG. 16, taking as an example manufacturing of five layered multilayered circuit substrate including the electric circuit 12 shown in FIG. 1.

As Step S1, a via hole 101 that corresponds to the electric circuit 12 is provided in each of the substrate sheets 11a to 11e. Specifically, in prepreg or ceramic as the substrate sheet, a through hole is processed using a laser or the like, and the through hole is filled with a conductive paste made of a Cu powder and a thermosetting epoxy resin, to form the via hole 101.

Next, as Step S2, the inspection via hole 1a is formed in the same manner as the via hole 101. It is to be noted that Step S1 and Step S2 may be performed simultaneously.

Next, as Step S3, firstly, the circuit electrode 102 and the conduction electrode 1c are provided on each main face of the substrate sheets 11a to 11e, to individually complete a double-sided circuit substrates.

The details of Step S3 are as follows. On each main face of the substrate sheets 11a to 11e provided with via holes, a 12 μm copper foil is arranged, which is heated and pressed (200° C., 50 kg/cm²) by heat-pressing, and subsequently etched to form a circuit pattern. Secondly, the double-sided circuit substrates are laminated to complete a substrate sheet laminate. Specifically, on a working stage, the metal foil having a thickness of 12 μm, the prepreg, the double-sided circuit substrate, the prepreg, and the metal foil are laminated on this order. These are each positioned by image recognition or the like, using a position determination pattern, and then laminated.

Next, the metal foil of the outermost fade is heated and pressed from above using a heated heater-chip or the like, to melt a resin component of the substrate sheets 11a to 11e, and due to hardening of the resin component, the metal foil is bonded to the double-sided circuit substrates, to complete the substrate sheet laminate 10. At this stage, the electric circuit 12 and the inspection mark structure 1 are formed inside the substrate sheet laminate 10. Further, up to this stage, the wire 2a is provided in the inspection mark structure 1.

Next, as Step S4, the substrate sheet laminate 10 is subjected to heat-pressing, to complete a multilayered circuit substrate. Specifically, the whole surface of the substrate sheet laminate 10 is heated and pressed (200° C., 50 kg/cm²), to bond the metal foil to each of the substrate sheets 11a to 11e, and the circuit pattern of the double-sided circuit substrate and the copper foil are inner-via connected by the conductive paste filling the through hole located between the circuit pattern and the copper foil. Further, the metal foil of the outermost layer is selectively etched to form a circuit pattern, so that the multilayered circuit substrate is formed.

Next, as Step S5, the galvanometer 2b is connected to the wire 2a of the completed multilayered circuit substrate, and checks conduction in the inspection mark structure 1. Based upon this, lamination matching precision of the multilayered circuit substrate is determined as Step S6.

At this time, in the case of using the inspection mark structure of Embodiment 1, the occurrence or non-occurrence of displacement is determined as the lamination matching precision. Further, in the case of using the inspection mark structure of Embodiment 2, 3 or 5, the occurrence or non-occurrence of displacement and the direction of displacement are determined as the lamination matching precision. Moreover, in the case of using the inspection mark structure of Embodiment 4, the occurrence or non-occurrence of displacement and the size of displacement are determined as the lamination matching precision.

When the lamination matching precision is determined to be preferred, the completed multilayered circuit substrate is a non-defective product, and the foregoing steps are thus repeated as Step S7, to continue manufacturing of the multilayered circuit substrate. The lamination matching precision here is the occurrence or non-occurrence of displacement, and this can facilitate realization of separate inspection on the multilayered circuit substrates.

On the other hand, when the lamination matching precision is determined not to be preferred, the completed multilayered circuit substrate is a defective product, and thus disposed.

Here, in the case of determining the lamination matching precision by means of the inspection mark structure of Embodiment 2 to 5 as the inspection mark structure, based upon the determination result, the direction of displacement or the size of displacement is clearly found. Thereat, as Step S8, the laminated positions of the substrate sheets 11a to 11e as the double-sided circuit substrates are corrected through the use of the clearly found direction of displacement or size of displacement, to form the multilayered circuit substrate 10.

Subsequently, operations after Step S4 are continued, to complete the multilayered circuit substrate based upon the substrate sheet laminate 10 after the laminated position has been corrected.

It is to be noted that in the above steps, Steps S4 and S5 correspond to the method for inspecting lamination matching precision of a multilayered circuit substrate according to the present invention, and Step S8 corresponds to the method for designing a substrate sheet laminate according to the present invention.

As thus described, according to the method for manufacturing a multilayered circuit substrate in accordance with the present embodiment, by including the method for inspecting the lamination matching precision by means of the inspection mark structure of Embodiment 1 to 5 in a series of manufacturing steps, it is possible to objectively determine whether the multilayered circuit substrate is in the normal or defective state.

Further, by feeding the direction and the size of displacement obtained from results of lamination matching precision inspection back to manufacturing conditions for a multilayered circuit substrate to be manufactured next time, it is possible to improve a yield of the multilayered circuit substrate.

It is to be noted that, although the object to be corrected as the predetermined design condition of the present invention was the laminated position of each of the substrate sheets 11a to 11e, the design condition may be the arrangement, the size, or the like, of the via hole or the circuit electrode in each substrate sheet. It may also be the number of substrate sheet layers. In short, an arbitrary numeral value may be the design condition so long as being a parameter necessary for manufacturing of the multilayered circuit substrate.

In addition, in the above embodiments, the inspection mark structures 1, 50a, 50b, 51a, 51b, 70 to 72, 80 to 83 and 90 correspond to the inspection mark structure of the present invention.

Further, the inspection via hole 1a corresponds to the inspection via hole of the present invention.

Further, the round pattern electrodes 1b, 1b′ correspond to the round pattern electrode of the present invention.

Further, the sub-pattern electrodes 3a to 3d, 6a, 6b, 7a, 7b, 8a to 8d, 8e to 8h correspond to the sub-pattern electrode of the present invention.

Further, the conduction electrode 1c, 1c′ corresponds to the condition electrode of the present invention.

Further, the opening 1e, 1e′, 80e to 83e in the round pattern electrode in the inspection mark structure or the inspection mark structure group of Embodiments 1, 2 and 4 corresponds to the shape of continuously surrounding the end face of the inspection via hole according to the present invention.

Further, the region formed between the sub-pattern electrodes 3a to 3d, 6a, 6b, 7a, 7b and the inspection via hole 1a in the round pattern electrode in the inspection mark structure of Embodiment 3 corresponds to the shape of surrounding, with cuts, the end face of the inspection via hole.

However, the present invention is not restricted to the above embodiments.

In Embodiment 1, the shape of continuously surrounding the end face of the inspection via hole was formed as the shape of the opening 1e. For example, as shown in FIG. 17, a notch may be provided at part of the edge of the round pattern electrode 1b. In this case, the opening corresponds to the shape of surrounding, with cuts, the end face of the inspection via hole according to the present invention.

Further, although the shape of any end face of the inspection via hole 1a was circular, it may be an arbitrary shape such as square or rectangular. So long as the shape of the opening of the corresponding round pattern electrode is similar to the shape of the end face, the inspection mark structure of Embodiment 1 or the inspection mark structure group of Embodiment 4 can be realized.

Further, even if the shape of the opening of the corresponding round pattern electrode is not similar to the shape of the end face, so long as the openings have the relation where the shapes thereof are identical to each other and the arrangements thereof inside the round pattern electrode do not match each other, the inspection mark structure group of Embodiment 2 can be realized.

Further, although the descriptions were given on the above embodiments assuming that the present invention is implemented by taking as an example the substrate sheet laminate formed by laminating a plurality of substrate sheets 11a to 11e and the multilayered circuit substrate formed by performing heat-pressing on the substrate sheet laminate, the present invention is not restricted by them, and may be implemented in manufacturing of a module formed by laminating a plurality of completed multilayered circuit substrates.

This is because it allows inspection of the lamination matching precision among the multilayered circuit substrates. At this time, the laminated multilayered circuit substrates may be those including an electric component such as a semiconductor device on the surface thereof or therebetween, and the effect of the present invention is exerted even in adjustment of positioning of those electronic components.

Further, the present invention may be implemented in an inspection of a fired matter of the substrate sheet laminate made up only of the substrate sheet not having the electric circuit 12. In this case, the present invention can be used for inspecting physical properties such as an extension property and a shrinkage property at the time of performing heat-pressing on prepreg or ceramic to be used in the substrate sheet.

The inspection mark structure according to the present invention has the effect of being able to objectively performing a lamination matching precision inspection, and is effective as, for example, an inspection mark structure, a substrate sheet laminate, a multilayered circuit substrate, a method for inspecting lamination matching precision of a multilayered circuit substrate, a method for designing a substrate sheet laminate, and the like.

What is claimed is:

1. An inspection mark structure, comprising:
an inspection via hole, which is provided in any of substrate sheets constituting at least two layers of substrate sheet laminates;
a round pattern electrode, which is formed on one face side of said substrate sheet provided with said inspection via hole, and provided around the end face of said inspection via hole at such a predetermined distance as not to come into contact with said end face; and
a conduction electrode, which is formed on the other face side of said substrate sheet provided with said inspection via hole, and provided so as to be electrically connected with the end face of said inspection via hole.

2. The inspection mark structure according to claim 1, wherein said round pattern electrode has a shape of continuously surrounding said end face of said inspection via hole.

3. The inspection mark structure according to claim 2, wherein the shape of continuously surrounding said end face of said inspection via hole is similar to the shape of said end face of said inspection via hole.

4. The inspection mark structure according to claim 2, wherein the shape of continuously surrounding said end face of said inspection via hole is not similar to the shape of said end face of said inspection via hole.

5. The inspection mark structure according to claim 1, wherein said round pattern electrode has the shape of surrounding, with cuts, said end face of said inspection via hole.

6. The inspection mark structure according to claim 5, wherein said round pattern electrode is made up of a plurality of sub-pattern electrodes provided around the end face of said inspection via hole.

7. The inspection mark structure according to claim 6, wherein said sub-pattern electrode is arranged point-symmetrically with the end face of said inspection via hole.

8. The inspection mark structure according to claim 7, wherein two or four of said sub-pattern electrodes having an identical shape are evenly spaced around the end face of said inspection via hole.

9. An inspection mark structure group, comprising a plurality of inspection mark structures according to claim 1,
wherein said predetermined distance between said round pattern electrode and said inspection via hole varies in each or part of said inspection mark structures.

10. An inspection mark structure group, comprising a plurality of inspection mark structures according to claim 4, wherein
said shape of continuously surrounding the end face of said inspection via hole in said round pattern electrode in each inspection mark structure is identical, and
arrangements of said shapes do not match one another.

11. The inspection mark structure group according to claim 10, wherein,
in each of said inspection mark structures,
the shape of said end face of said inspection via hole is circular,
said shape of continuously surrounding said end face of said inspection via hole in said round pattern electrode is oblong or elliptic and said oblong or elliptic shapes are orthogonal to each other.

12. A substrate sheet laminate, comprising:
a circuit electrode provided on a substrate sheet having a via hole; and
an inspection mark structure according to claim 1 formed on said substrate sheet.

13. The substrate sheet laminate according to claim 12, wherein
said inspection mark structures are provided in a plurality of numbers,
the shape of continuously surrounding said end face of said inspection via hole in said round pattern electrode in said inspection mark structure is not similar to the shape of said end face of said inspection via hole,
said shape continuously surrounding said end face of said inspection via hole in said round pattern electrode in each inspection mark structure is identical, and
arrangements of said shapes do not match each other.

14. A multilayered circuit substrate, formed by performing heat-pressing on a substrate sheet laminate according to claim 12.

15. An inspection mark structure, comprising:
an inspection via hole, which is provided in any of substrate sheets constituting at least two layers of substrate sheet laminates;
a round pattern electrode, which is formed on one face side of said substrate sheet provided with said inspection via hole, and provided around the end face of said inspection via hole so as to come into contact with said end face; and
a conduction electrode, which is formed on the other face side of said substrate sheet provided with said inspection via hole, and provided so as to be electrically connected with the end face of said inspection via hole.

16. The inspection mark structure according to claim 15, wherein said round pattern electrode is provided around the end face of said inspection via hole, and made up of a plurality of sub-pattern electrodes each in contact with said end face.

17. The inspection mark structure according to claim 16, wherein said sub-pattern electrode is arranged point-symmetrically with the end face of said inspection via hole.

18. An inspection mark structure group, comprising a plurality of inspection mark structures according to claim 15,
wherein the outer diameter of the end face of said inspection via hole varies in each or part of said inspection mark structures.

19. A substrate sheet laminate, comprising:
a plurality of substrate sheets having a via hole;
a circuit electrode provided on said plurality of substrate sheet layers; and
an inspection mark structure according to claim 15 formed on said plurality of substrate sheet layers.

20. The substrate sheet laminate according to claim 19, wherein
said inspection mark structures are provided in a plurality of numbers, and
a size of a contacting portion of the end face of said inspection via hole and said round pattern electrode in said inspection mark structure varies in each or part of a plurality of said inspection mark structures.

21. A multilayered circuit substrate, formed by performing heat-pressing on a substrate sheet laminate according to claim 18.

22. A method for inspecting lamination matching precision of a multilayered circuit substrate having:
a plurality of substrate sheets having a via hole;
a circuit electrode provided on said plurality of substrate sheet layers; and
an inspection mark structure formed on said plurality of substrate sheet layers, said structure including an inspection via hole which is provided in any of substrate sheets constituting at least two layers of substrate sheet laminates, a round pattern electrode which is formed on one face side of said substrate sheet provided with said inspection via hole and provided around the end face of said inspection via hole at such a predetermined distance as not to come into contact with said end face or so as to come into contact with said end face, and a conduction electrode which is formed on the other face side of said substrate sheet provided with said inspection via hole and provided so as to be electrically connected with the end face of said inspection via hole,
said method comprising the steps of:
electrically connecting said conduction electrode and said round pattern electrode in said inspection mark structure; and
determining that said lamination matching precision is held (A) when conduction does not occur by said connection in the case of said inspection mark structure having said round pattern electrode provided around the end face of said inspection via hole at such a predetermined distance as not to come into contact with said end face, or (B) when conduction occurs by said connection in the case of said inspection mark structure having said round pattern electrode provided around the end face of said inspection via hole so as to come into contact with said end face.

23. The method for inspecting lamination matching precision of a multilayered circuit substrate according to claim 22, wherein said lamination matching precision is at least one of occurrence or non-occurrence of displacement between substrates constituting said multilayered circuit substrate, and a direction and a size of the displacement.

24. A method for designing a substrate sheet laminate, comprising the steps of:
forming a testing substrate sheet laminate by laminating said plurality of substrate sheets where an inspection mark structure is formed such that a circuit electrode is located between layers of the substrate sheet, said inspection mark structure having an inspection via hole which is provided in any of substrate sheets constituting at least two layers of substrate sheet laminates formed in a plurality of substrate sheets having a via hole in a predetermined design condition, a round pattern electrode which is formed on one face side of said substrate sheet provided with said inspection via hole and provided around the end face of said inspection via hole at such a predetermined distance as not to come into contact with said end face or so as to come into contact with said end face, and a conduction electrode which is formed on the other face side of said substrate sheet provided with said inspection via hole and provided so as to be electrically connected with the end face of said inspection via hole;
performing heat-pressing on said testing substrate sheet laminate, to form a testing multilayered circuit substrate;
acquiring a direction or a size of displacement of said substrate as said lamination matching precision of said testing multilayered circuit substrate by the use of a method for inspecting lamination matching precision of a multilayered circuit substrate according to claim 22; and
correcting said predetermined design condition by the use of the acquired direction or size of displacement of said substrate.

25. The method for designing a substrate sheet laminate according to claim 24, wherein said predetermined design condition is a position of lamination of each of said plurality of substrate sheets.
